(19) United States
(12) Patent Application Publication
(10) Pub. No.: US 2024/0006261 A1
(43) Pub. Date: Jan. 4, 2024

(54) PACKAGE HEATERS FOR COLD TEMPERATURE OPERATION AND METHOD

(71) Applicant: Intel Corporation, Santa Clara, CA (US)

(72) Inventors: Ganesh Kondapuram, Chandler, AZ (US); Chetan Rawal, Chandler, AZ (US); Kevin Connolly, Chandler, AZ (US); Robert Anderson, Elk Grove, CA (US)

(21) Appl. No.: 17/855,176

(22) Filed: Jun. 30, 2022

(51) Int. Cl. H01L 23/34; H01L 25/065; H01L 23/498

(52) U.S. Cl. CPC H01L 23/345; H01L 25/0655; H01L 23/49822; H01L 23/49866

(57) ABSTRACT

A semiconductor package comprises two or more dies including at least one integrated circuit. The package can further include a heater element. The heater element can be configured to radiate heat, within one or more of a metal layer and a diffusion layer of at least one of the two or more dies of the semiconductor package. The package can further include controller interface configured to receive a heater enablement signal to initiate or terminate operation of the heater element. Other systems, apparatuses and methods are described.

### TECHNICAL FIELD

Embodiments pertain to packaging of integrated circuits (ICs). Some embodiments relate to heating apparatuses for packages.

### BACKGROUND

Industrial and embedded systems are expected to operate in extreme environmental conditions. Systems and methods are available for dealing with high temperatures. However, integrated circuit (IC) packages can also be used in sub-zero temperatures that can lead to circuit functionality issues or failure of computing systems to boot up. There is a general need for systems to enable operation of industrial and embedded systems in sub-zero temperatures.

### BRIEF DESCRIPTION OF THE DRAWINGS

FIG. 1 is an illustration of a semiconductor package having a heater chiplet in accordance with some embodiments;

FIG. 2 illustrates temperature thresholds for enabling and disabling heater chiplets according to some embodiments;

FIG. 3 illustrates a process of providing heat during a boot operation in accordance with some embodiments;

FIG. 4 illustrates a process of providing heat during an on-die boot controller sequence in accordance with some embodiments;

FIG. 5 illustrates a system level diagram in accordance with some embodiments; and

FIG. 6 illustrates an interposer heater positioned between a semiconductor package and a mother board in disaggregated package solutions in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Electronic systems often include integrated circuits (ICs) that are attached to substrate materials and packaged as a semiconductor package. Semiconductor packages included in industrial systems or other embedded systems are expected to operate in extreme environmental conditions. These conditions include sub-zero temperatures in addition to temperatures higher than what is typically required in consumer systems.

Higher temperatures can be accommodated by throttling or implementing more robust thermal solutions at the system level, but sub-zero temperatures can lead to circuit functionality issues that could prevent the system from booting.

Aspects of the disclosure address these and other concerns by providing heating to enable operation of industrial and embedded systems in sub-zero temperatures. Some previous solutions addressed these concerns by adding heaters at metal portions of the semiconductor packages, but these led to geometry issues and issues with tradeoffs in area and board layout. In contrast, in some embodiments, a thermal element can be integrated into chiplets in disaggregated packaging technologies, while in still other embodiments, a thermal element can be integrated into a package level interposer, and the thermal element in either embodiment can be configured to radiate heat to at least one nearby component. The interposer applies a controlled level of heat to improve package/product operation and long-term solder joint reliability. Embodiments therefore can provide heating while reducing or eliminating the impact on board geometry, cost, and other factors.

Recently, semiconductor manufacturers have begun separating systems into multiple chiplets according to a technology known as disaggregation. In some embodiments, one or more of the chiplets in a disaggregated system can be used as a local heater. This heater chiplet can generate heat in a semiconductor package bringing any other dies or chiplets in the system to the designed operating range.

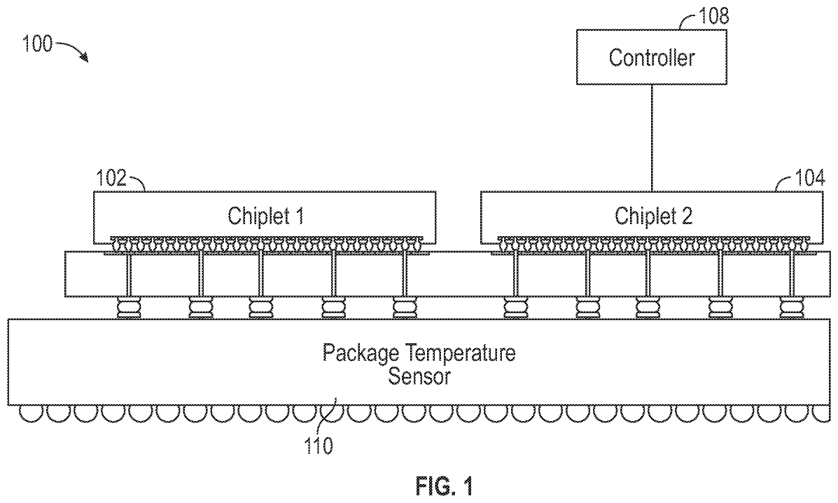

FIG. 1 is an illustration of a semiconductor package 100 in accordance with some embodiments. In some examples, semiconductor packages can include two or more chiplets 102, 104, which can be stacked as shown in FIG. 1 in, for example, a three-dimensional (3D) fashion. One of the chiplets 102 can include processing circuitry, whereas another chiplet 104 can include a heater element. While two chiplets 102, 104 are shown, the package 100 can include more than two chiplets. Furthermore, more than one chiplet 104 can include a heater element. The chiplet 104 or other chiplets (not shown in FIG. 1) can include structural dies comprised of blank silicon, copper traces to enhance thermal conductivity, or other elements. In some embodiments, structural dies can include metal or diffusion layer heaters. In some embodiments, the semiconductor package 100 size can be increased to include additional heater chiplets or other chiplets.

Once the heater is implemented in a chiplet 104, an embedded controller 108 can be included outside the semiconductor package 100 to control the heating element. The Minimum Operating Temperature Threshold (MOTT) is a defined as the CPU design point, below which the system cannot be booted (OC, as an example). A package temperature sensor 110 can be included to sense temperature before on-die thermal sensors (not shown in FIG. 1) are available.

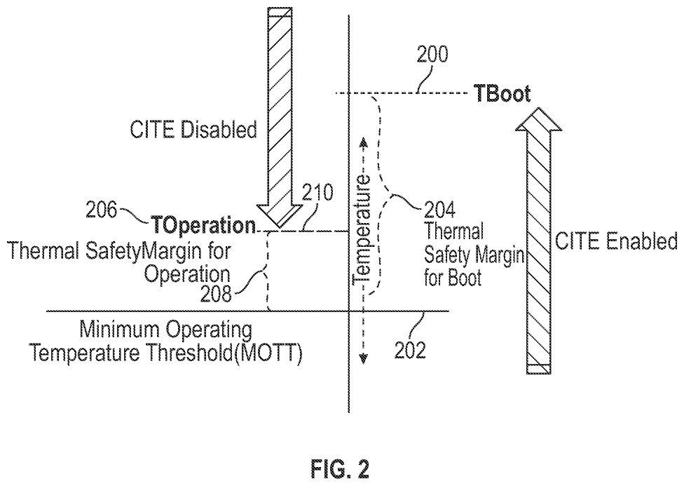

FIG. 2 illustrates temperature thresholds for enabling and disabling heater chiplets (e.g., chiplet 104 (FIG. 1)) according to some embodiments. The embedded controller 108 can control the booting process, e.g., the embedded controller 108 can monitor temperatures to control whether booting will occur and can maintain temperature stability after booting through further monitoring of temperature.

The embedded controller 108 can enforce safety margins around the MOTT. One temperature threshold 200, can be equal to about MOTT 202 plus a safety margin 204. A second, lower threshold 206 can equal MOTT 202 plus a smaller safety margin 208 for operation. Before the system (e.g., semiconductor package 100 boots, on-die thermal sensors are not accessible, so the package temperature sensor 110 (FIG. 1) is used to determine when to enable the heater chiplets. If the package temperature is below threshold 200, the heater chiplets (e.g., chiplet 104 (FIG. 1)) can be enabled or providing heat to the semiconductor package 100.

The embedded controller 108 can sample the package temperature (measured by, e.g., the package temperature sensor 110) at regular intervals until the temperature meets or exceeds the temperature threshold 200. Once the package temperature meets or exceeds threshold 200, the embedded controller 108 can provide instructions to the heater chiplets (e.g., the chiplet 104 (FIG. 1) to terminate heating operations. Booting operations or other operations can then be permitted to commence and the semiconductor package 100 can commence normal operations.

During normal operation, on-die thermal sensors can be used to monitor the processor temperature and ensure that temperature remains above TOperation. As long as temperature remains above threshold 210. If the temperature drops to below threshold 210, the embedded controller 108 can provide instructions to the heater chiplets (e.g., chiplet 104) to provide heat to bring the semiconductor package 100 temperature above threshold 210.

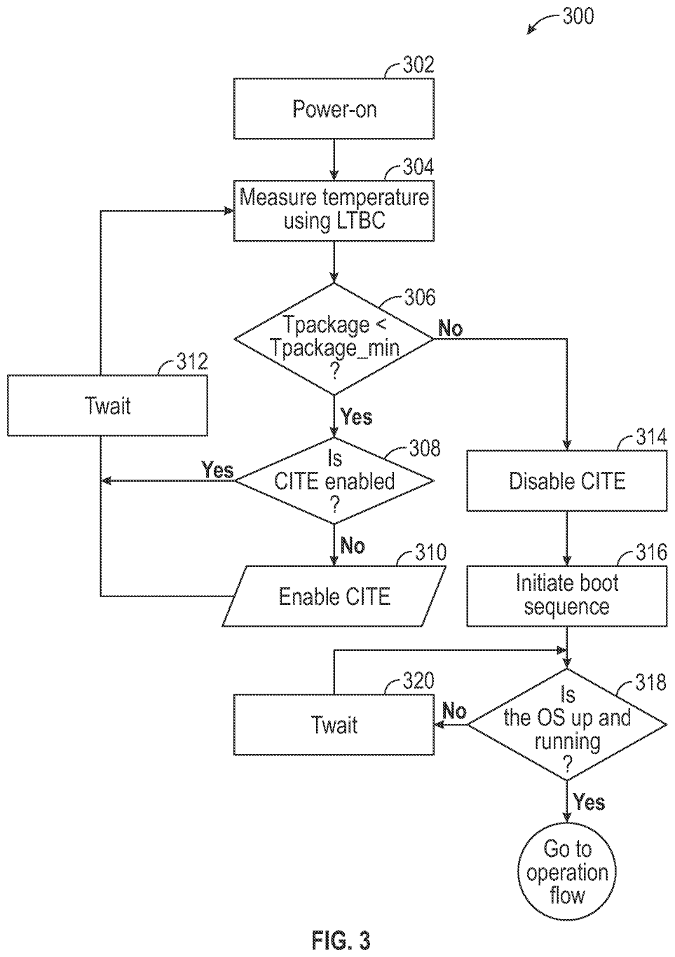

FIG. 3 illustrates a process 300 of providing heat during a boot operation in accordance with some embodiments. The operations of process 300 can be performed by, for example, the embedded controller 108 (FIG. 1). In FIG. 3, the temperature T_{package_min} can be defined as the minimum temperature at which heater chiplets (e.g., chiplet 104 (FIG. 1)) are enabled, or provide heat. T_{package_min} can also be defined as threshold 200 minus a delta temperature T_{package_delta}, where T_{package_delta} is based on the semiconductor package 100 type and can vary further based on package material.

At operation 302, during power on during boot phase, the embedded controller 108 can examine a Boot Status register bit (BSR bit). If the system is not booted, then at operation 304 the embedded controller 108 can monitor package temperature using, for example, the package temperature sensor 110.

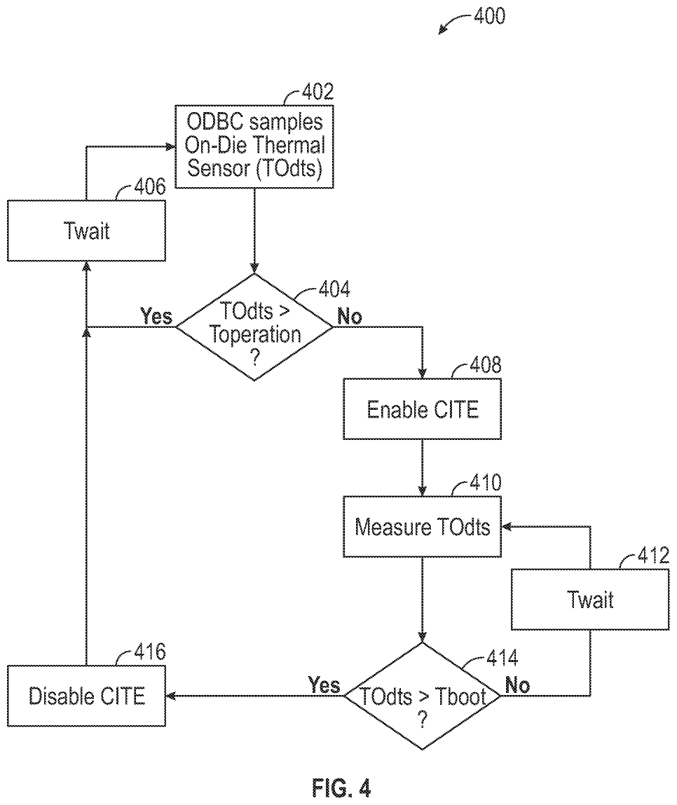

At block 306, if the package temperature is below a minimum, the embedded controller 108 can enable the heater chiplets 104 (FIG. 1) if they are not enabled (blocks 308 and 310) and wait a time period at block 312 before measuring temperature of the package again. Otherwise, if the package temperature is greater than a minimum, the embedded controller 108 can disable heater chiplets at block 314 and initiate a boot sequence at operation 316. Once the operating system associated with the semiconductor package 100 is running (at operation 318), an on-die boot controller sequence (operation sequence) described with reference to FIG. 4 can be initiated. Otherwise, the embedded controller 108 will wait in a wait sequence at block 320 for the operating system to commence operation.

FIG. 4 illustrates a process 400 of providing heat during an on-die boot controller sequence in accordance with some embodiments. The operations of process 300 can be performed by, for example, the embedded controller 108 (FIG. 1). After the system boots to an operating system as described at operation 318 (FIG. 3), the embedded controller 108 can monitor die temperature at operation 402 using the On-Die Thermal Sensors (e.g., the package temperature sensors 110 are no longer required to monitor package temperature but rather other temperature sensors outside the semiconductor package 100 can be used. At block 404, if the temperature detected by on-die thermal sensors is greater than an operational threshold (e.g., threshold 210 (FIG. 2)), then the embedded controller 108 can wait for an amount of time at block 406 before checking temperature again. Otherwise, at operation 408 the embedded controller 108 can enable heater chiplets 104 and continue measuring temperature at operation 410 periodically according to a time period 412. Once the temperature surpasses threshold 200, as measured at operation 414, the heater chiplets 104 are disabled at operation 416 and operation again commences at the waiting block 406.

In other embodiments, rather than providing a heater chiplet 104 (FIG. 1), the semiconductor package 100 can be provided with a thermal element integrated into a package level interposer. The interposer applies a controlled level of heat to improve semiconductor package 100 operation and long-term solder joint reliability. Similar to heater chiplet-based systems, the thermal element in these embodiments can heat semiconductor packages to a deigned operating range.

The methods, devices, and systems described herein provide heating mechanisms to bring semiconductor packages into operational ranges, preventing damage to components that can be caused by operating at lower-than-desired temperatures. An example of an electronic device using assemblies with system level packaging as described in the present disclosure is included to show an example of a higher level device application.

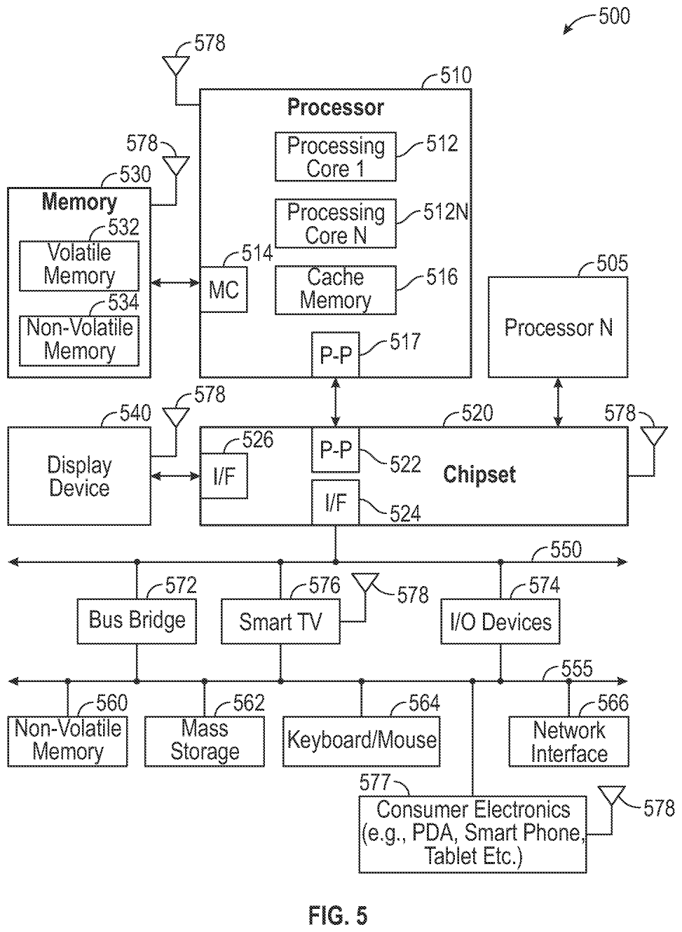

FIG. 5 illustrates a system level diagram, according to one embodiment of the invention. For instance, FIG. 5 depicts an example of a system that can include an electronic device packaged layers of interface material that can vary in impedance as failures (e.g., cracks, liquid incursions, etc.) are detected in the interface material. with a substrate including at least one layer of dielectric material comprised of at least a portion of diamond dust material. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance, or any other type of computing device. In some embodiments, system 500 is a system on a chip (SOC) system. In some embodiments, some components can be included in vehicular systems (e.g., automotive, avionics, etc.). The device can include one or more semiconductor dies, which can include microprocessors, SoCs, etc.

In one embodiment, processor 510 has one or more processing cores 512 and 512N, where N is a positive integer and 512N represents the Nth processor core inside processor 510. In one embodiment, system 500 includes multiple processors including 510 and 505, where processor 505 has logic similar or identical to the logic of processor 510. In some embodiments, processing core 512 includes, but is not limited to, pre-fetch logic to fetch instructions, decode logic to decode the instructions, execution logic to execute instructions and the like. In some embodiments, processor 510 has a cache memory 516 to cache instructions and/or data for system 500. Cache memory 516 may be organized into a hierarchal structure including one or more levels of cache memory.

In some embodiments, processor 510 includes a memory controller 514, which is operable to perform functions that enable the processor 510 to access and communicate with memory 530 that includes a volatile memory 532 and/or a non-volatile memory 534. In some embodiments, processor 510 is coupled with memory 530 and chipset 520. Processor 510 may also be coupled to a wireless antenna 578 to communicate with any device configured to transmit and/or receive wireless signals. In one embodiment, the wireless antenna interface 578 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interfaces 517 and 522. Chipset 520 enables processor 510 to connect to other elements in system 500. In some embodiments of the invention, interfaces 517 and 522 operate in accordance with a PtP communication protocol such as the Intel® QuickPath Interconnect (QPI) or the like. In other embodiments, a different interconnect may be used.

In some embodiments, chipset 520 is operable to communicate with processor 510, 505N, display device 540, and other devices 572, 576, 574, 560, 562, 564, 566, 577, etc. Buses 550 and 555 may be interconnected together via a bus bridge 572. Chipset 520 connects to one or more buses 550 and 555 that interconnect various elements 574, 560, 562, 564, and 566. Chipset 520 may also be coupled to a wireless antenna 578 to communicate with any device configured to transmit and/or receive wireless signals. Chipset 520 connects to display device 540 via interface (I/F) 526. Display device 540 may be, for example, a touchscreen, a liquid crystal display (LCD), a plasma display, cathode ray tube (CRT) display, or any other form of visual display device. In some embodiments of the invention, processor 510 and chipset 520 are merged into a single SOC. In one embodiment, chipset 520 couples with (e.g., via interface 524) a non-volatile memory 560, a mass storage medium 562, a keyboard/mouse 564, and a network interface 566 via OF 524 and/or OF 526, I/O devices 574, smart TV 576, consumer electronics 577 (e.g., PDA, Smart Phone, Tablet, etc.).

In one embodiment, mass storage medium 562 includes, but is not limited to, a solid state drive, a hard disk drive, a universal serial bus flash memory drive, or any other form of computer data storage medium. In one embodiment, network interface 566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 5 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 (or selected aspects of 516) can be incorporated into processor core 512.

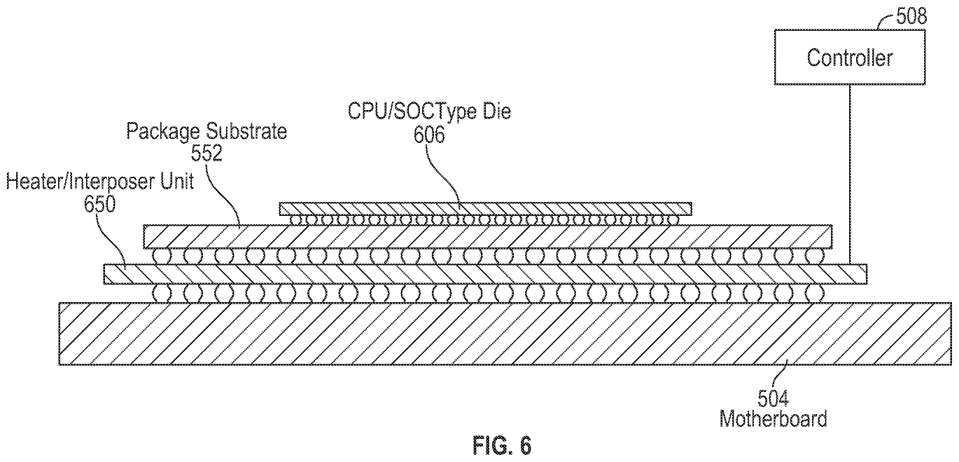

FIG. 6 illustrates an interposer heater 650 positioned between a semiconductor package 552 and a motherboard 504 in disaggregated package solutions in accordance with some embodiments. The interposer heater 650 can include copper serpentines (or other-shaped designs comprised of other types of metal or conductive elements) that are configured to develop enough resistance to generate heat. Serpentines can be added to multiple layers to generate enough heat for the application. Interposers are designed similar to packages with layers of copper separated by dielectric material. Copper thickness and width can be adjusted for custom applications, and embodiments are not limited to copper but can include other metals or conductive material. Other operational dies 606, such as central processing unit (CPU) dies or system on chip (SoC) dies can be included on the package. A controller 508 can operate similarly to embedded controller 108 (FIG. 1) to control heating operations similarly to those described above with respect to FIG. 2-4.

The devices, systems, and methods described can provide improved thermal conductivity in electronic device packages. Examples described herein include one SoC for simplicity, but one skilled in the art would recognize upon reading this description that the examples can include more than one SoC system.

### ADDITIONAL DESCRIPTION AND EXAMPLES

Example 1 is a semiconductor package comprising two or more dies including at least one integrated circuit; a heater element configured to radiate heat, within one or more of a metal layer and a diffusion layer of at least one of the two or more dies of the semiconductor package; and a controller interface configured to receive a heater enablement signal to initiate or terminate operation of the heater element.

In Example 2, the subject matter of Example 1 can optionally include wherein the heater element is disposed within an interposer portion, the interposer portion composed of a plurality of copper layers separated by dielectric material, the interposer portion being disposed between a motherboard and processing circuitry, wherein the heater element is configured to provide heat for the two or more dies.

In Example 3, the subject matter of Example 2 can optionally include wherein the heater element comprises conductive elements in at least one layer of the interposer layer.

In Example 4, the subject matter of Example 3 can optionally include wherein the conductive elements comprise copper serpentines.

In Example 5, the subject matter of Example 3 can optionally include wherein the conductive elements are provided within two or more layers of the interposer layer.

In Example 6, the subject matter of Example 3 can optionally include wherein the heater element is disposed within a dedicated heater die of the semiconductor package, and wherein the heater element is configured to provide heat for at least one other die of the two or more dies of the semiconductor package.

In Example 7, the subject matter of Example 6 can optionally include wherein the interposer portion is composed of a plurality of copper layers separated by dielectric material, the interposer portion being disposed between a motherboard and processing circuitry of the at least one of the two or more dies, wherein the heater element is configured to provide heat for a respective one of the two or more dies.

In Example 8, the subject matter of Example 6 can optionally include wherein the dedicated heater die is a structural silicon component of the semiconductor package.

Example 9 is a system comprising at least one semiconductor package comprising: two or more dies including at least one integrated circuit; and a heater element, comprised of a thermal element that radiates heat, within one or more of a metal layer and a diffusion layer of at least one of the two or more dies of the semiconductor package; and control circuitry to provide a heater enablement signal to the heater element to initiate or terminate operation of the heater element.

In Example 10, the subject matter of Example 9 can optionally include wherein the heater element is disposed within an interposer portion, the interposer portion composed of a plurality of copper layers separated by dielectric material, the interposer portion being disposed between a motherboard and processing circuitry of the at least one of the two or more dies, wherein the heater element is configured to provide heat for a respective one of the two or more dies.

In Example 11, the subject matter of Example 10 can optionally include wherein the heater element comprises conductive elements in at least one layer of the interposer layer.

In Example 12, the subject matter of Example 11 can optionally include wherein the conductive elements comprise copper serpentines.

In Example 13, the subject matter of Example 11 can optionally include wherein the conductive elements are provided within two or more layers of the interposer layer.

In Example 14, the subject matter of Example 11 can optionally include wherein the heater element is disposed within a dedicated heater die of the semiconductor package, and wherein the heater element is configured to provide heat for at least one other die of the two or more dies of the semiconductor package.

In Example 15, the subject matter of Example 14 can optionally include wherein at least one of the two or more dies other than the dedicated heater die includes an interposer portion, the interposer portion composed of a plurality of copper layers separated by dielectric material, the interposer portion being disposed between a motherboard and processing circuitry of the at least one of the two or more dies, wherein the heater element is configured to provide heat for the respective one of the two or more dies.

In Example 16, the subject matter of Example 14 can optionally include wherein the dedicated heater die is a structural silicon component of the semiconductor package.

In Example 17, the subject matter of any of Examples 9-16 can optionally include at least one other semiconductor package, and wherein the semiconductor package and the at least one other semiconductor package comprise a disaggregated chipset.

In Example 18, the subject matter of any of Examples 9-17 can optionally include at least one package temperature sensor, and wherein the controller is configured to disable booting of the system until a temperature of the system is at least equal to a boot temperature specified for the system.

Example 19 is a method of operating a semiconductor package, the method comprising receiving a signal at a computing system to boot the computing system; measuring temperature of at least one processing circuitry component or an ambient temperature around the at least one processing circuitry component; and if the temperature is below a boot temperature threshold, provide a command to refrain from booting the computing system, and provide a command to the heater element to provide heat to the semiconductor package.

In Example 20, the subject matter of Example 19 can optionally include monitoring the temperature for a time period; and providing a command to boot the computing system and to disable the heater element upon the temperature rising above the boot temperature threshold.

These non-limiting examples can be combined in any permutation or combination. The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. A semiconductor package comprising:
two or more dies including at least one integrated circuit;
a heater element configured to radiate heat, within one or more of a metal layer and a diffusion layer of at least one of the two or more dies of the semiconductor package; and
a controller interface configured to receive a heater enablement signal to initiate or terminate operation of the heater element.

2. The semiconductor package of claim 1, wherein the heater element is disposed within an interposer portion, the interposer portion composed of a plurality of copper layers separated by dielectric material, the interposer portion being disposed between a motherboard and processing circuitry, wherein the element circuit is configured to radiate heat to the two or more dies.

3. The semiconductor package of claim 2, wherein the heater element comprises conductive elements in at least one layer of the interposer layer.

4. The semiconductor package of claim 3, wherein the conductive elements comprise copper serpentines.

5. The semiconductor package of claim 3, wherein the conductive elements are provided within two or more layers of the interposer layer.

6. The semiconductor package of claim 3, wherein the heater element is disposed within a dedicated heater die of the semiconductor package, and wherein the heater element is configured to radiate heat to at least one other die of the two or more dies of the semiconductor package.

7. The semiconductor package of claim 6, wherein the interposer portion is composed of a plurality of copper layers separated by dielectric material, the interposer portion being disposed between a motherboard and processing circuitry of the at least one of the two or more dies, wherein the heater element is configured to radiate heat to a respective one of the two or more dies.

8. The semiconductor package of claim 6, wherein the dedicated heater die is a structural silicon component of the semiconductor package.

9. A system comprising:
at least one semiconductor package comprising:
two or more dies including at least one integrated circuit; and
a heater element configured to radiate heat, within one or more of a metal layer and a diffusion layer of at least one of the two or more dies of the semiconductor package; and
control circuitry to provide a heater enablement signal to the heater circuit to initiate or terminate operation of the heater element.

10. The system of claim 9, wherein the heater element is disposed within an interposer portion, the interposer portion composed of a plurality of copper layers separated by dielectric material, the interposer portion being disposed between a motherboard and processing circuitry of the at least one of the two or more dies, wherein the heater element is configured to radiate heat to a respective one of the two or more dies.

11. The system of claim 10, wherein the heater element comprises conductive elements in at least one layer of the interposer layer.

12. The system of claim 11, wherein the conductive elements comprise copper serpentines.

13. The system of claim 11, wherein the conductive elements are provided within two or more layers of the interposer layer.

14. The system of claim 11, wherein the heater element is disposed within a dedicated heater die of the semiconductor package, and wherein the heater element is configured to radiate heat to at least one other die of the two or more dies of the semiconductor package.

15. The system of claim 14, wherein at least one of the two or more dies other than the dedicated heater die includes an interposer portion, the interposer portion composed of a plurality of copper layers separated by dielectric material, the interposer portion being disposed between a motherboard and processing circuitry of the at least one of the two or more dies, wherein the heater element is configured to radiate heat to the respective one of the two or more dies.

16. The system of claim 14, wherein the dedicated heater die is a structural silicon component of the semiconductor package.

17. The system of claim 9 further comprising at least one other semiconductor package, and wherein the semiconductor package and the at least one other semiconductor package comprise a disaggregated chipset.

18. The system of claim 9, further comprising at least one package temperature sensor, and wherein the controller is configured to disable booting of the system until a temperature of the system is at least equal to a boot temperature specified for the system.

19. A method of operating a semiconductor package, the method comprising:
receiving a signal at a computing system to boot the computing system;
measuring temperature of at least one processing circuitry component or an ambient temperature around the at least one processing circuitry component; and
if the temperature is below a boot temperature threshold, providing a command to refrain from booting the computing system, and provide a command to heater element to radiate heat to the semiconductor package.

20. The method of claim 19, further comprising:
monitoring the temperature for a time period; and
providing a command to boot the computing system and to disable the heater element upon the temperature rising above the boot temperature threshold.
